(19) United States
(12) Patent Application Publication
(10) Pub. No.: US 2021/0028230 A1
(43) Pub. Date: Jan. 28, 2021

(54) CROSSBAR ARRAY CIRCUIT WITH 3D VERTICAL RRAM

(71) Applicant: TETRAMEM INC., Newark, CA (US)

(72) Inventors: Minxian Zhang, Newark, CA (US); Ning Ge, Newark, CA (US)

(73) Assignee: TETRAMEM INC., Newark, CA (US)

(21) Appl. No.: 16/521,975

(22) Filed: Jul. 25, 2019

(51) Int. Cl. H01L 27/24; H01L 45/00

(52) U.S. Cl. CPC H01L 27/249; H01L 27/2436; H01L 45/1675; H01L 45/1233; H01L 45/146; H01L 45/1253; H01L 27/2418; H01L 45/1633

(57) ABSTRACT

Provided are 3D One-Transistor-N-RRAM (1TNR) structures and One-Selector-One-RRAM (1S1R) structures and methods for manufacturing the same. An example 3D 1TNR structure comprises: a plurality of gate lines; and a plurality of crossbar arrays (e.g., a first crossbar array and a second crossbar array). The first and second crossbar arrays are positioned on a first vertical plane and a second vertical plane, respectively. Each crossbar array in the plurality of crossbar arrays includes a first plurality of bit lines and a second plurality of word lines; Each word line in the second plurality of word lines is connected to a source and a destination of a second transistor; and each gate line in the plurality of gate lines is connected to a gate of a first transistor located in the first crossbar array and a gate of a second transistor located in the second crossbar array.

### TECHNICAL FIELD

The present disclosure generally related to crossbar array circuits with one or more three-dimension (3D) vertical RRAMs and more specifically to crossbar array circuits with one or more 3D vertical RRAMs having different architectures, as well as methods for manufacturing the same.

### BACKGROUND

Traditionally, a crossbar array circuit may include horizontal metal wire rows and vertical metal wire columns (or other electrodes) intersecting with each other, with crossbar devices formed at the intersecting points. A crossbar array may be used in non-volatile solid-state memory, signal processing, control systems, high-speed image processing systems, neural network systems, and so on.

A Resistive Radom Asses Memory (RRAM) is a two-terminal passive device capable of changing resistance responsive to predefined electrical stimulations, which have attracted significant attention for high-performance non-volatile memory applications. The resistance of a RRAM may be electrically switched between two states: a High-Resistance State (HRS) and a Low-Resistance State (LRS). The switching event from a HRS to a LRS is often referred to as a “Set” or “On” switch; the switching systems from a LRS to a HRS is often referred to as a “Reset” or “Off” switching process.

A selector is a two-terminal device that is capable of delivering voltage to a selected RRAM device. In a conventional 2D crossbar array circuit having a one-selector-one-memristor (1S1R) architecture, a RRAM and a selector are serially connected in order to reduce sneak path current, to improve the read and write operations, and to reduce array's power consumption.

### SUMMARY

Technologies relating to providing crossbar array circuits with one or more 3D vertical RRAMs having different architectures, as well as methods for manufacturing the same are disclosed.

An example 3D 1TNR (also referred to as a 3Done-transistor-N-RRAM) structure comprises: a plurality of gate lines; and a plurality of crossbar arrays (e.g., a first crossbar array and a second crossbar array). The first and second crossbar arrays are positioned on a first vertical plane and a second vertical plane, respectively. Each crossbar array in the plurality of crossbar arrays includes a first plurality of bit lines and a second plurality of word lines; Each word line in the second plurality of word lines is connected to a source and a destination of a second transistor; and each gate line in the plurality of gate lines is connected to a gate of a first transistor located in the first crossbar array and a gate of a second transistor located in the second crossbar array.

The plurality of crossbar arrays includes, in some implementations, a third crossbar array positioned on a third vertical plane different from both the first crossbar array and the second crossbar array.

The third crossbar array includes, in some implementations, a plurality of word lines and a plurality of bit lines, wherein each word line in the plurality of word lines is connected to a source and a destination of a third transistor.

A gate of a third transistor in the third crossbar array is, in some implementations, connected to a gate line in the plurality of gate lines.

An example method for manufacturing a crossbar array circuit, in some implementations, comprises: providing a substrate; alternatingly depositing, on the substrate, one or more RRAM metal layers and one or more dielectric layers to form an RRAM stack on the substrate; etching the RRAM stack to form a via; oxidizing the one or more RRAM metal layers through the via to form one or more RRAM oxide layers; forming a contact layer on a sidewall of the via; and forming a first electrode to fill the via.

The method, in some implementations, further comprises: forming one or more transistor arrays, integrated circuits, and interconnects on the substrate before forming the RRAM stack.

The method, in some implementations, further comprises: etching the RRAM stack to expose one or more upper surfaces of the one or more RRAM metal layers.

An example apparatus comprises: a substrate; an Inter-Layer Dielectric (ILD) formed on the substrate; an RRAM stack formed on the ILD. The RRAM stack comprises one or more metal layers and one or more dielectric layers alternatingly deposited on the ILD. The example apparatus further comprise: a via formed within the RRAM stack, wherein the via comprises a sidewall; an RRAM oxide layer formed on the sidewall of the via; a first contact layer formed on the RRAM oxide layer through the via; and a first electrode formed on the first contact layer and filled the via.

In some implementations, the substrate comprises one of: Si, SiO2, SiN, Al2O3, AlN, gallium arsenide, or glass.

In some implementations, the RRAM oxide layer is made of TaOx, HfOx, TiOx, ZrOx, or a combination thereof.

In some implementations, the first contact layer comprises: Pt, Pd, Ir, Ti, a combination thereof, or an alloy of a conductive material and one or more of: Pt, Pd, Ir, and Ti.

In some implementations, the first electrode comprises: Pt, Ti, TiN, Pd, Ir, W, Ta, Hf, Nb, V, TaN, NbN, a combination thereof, or an alloy of a conductive material and one or more of: Pt, Ti, TiN, Pd, Ir, W, Ta, Hf, Nb, V, TaN, NbN.

The apparatus, in some implementations, further includes: a selector layer formed between the first contact layer and the first electrode; and a second contact layer formed between the selector layer and the first electrode.

The selector layer, in some implementations, comprises an insulator-metal transition (IMT), a Mott transition, or a negative-differential-resistance (NDR). The selector layer, in some implementations, comprises NbOx; the second contact layer, in some implementations, comprises Nb.

An apparatus, in some implementations, includes: a substrate; an ILD formed on the substrate; a RRAM stack formed on the ILD, wherein the RRAM stack includes one or more metal layers and one or more dielectric layers alternatingly deposited on the ILD; a via formed within the RRAM stack, wherein the via includes a sidewall; a selector layer formed at the sidewall through the via; a RRAM oxide layer formed at the selector layer through the via; a first contact layer formed at the RRAM oxide layer; and a first electrode formed at the first contact layer and filled the via.

In some implementations, the RRAM oxide layer comprises TaOx, HfOx, TiOx, ZrOx, or the combinations thereof.

In some implementations, the selector layer comprises an insulator-metal transition (IMT), a Mott transition, or a negative-differential-resistance (NDR).

In some implementations, the apparatus includes a 3D one-selector-one-RRAM (1S1R) structure or a 3D one-transistor-N-RRAM (1TNR) structure.

### BRIEF DESCRIPTION OF THE DRAWINGS

FIG. 1A is a block diagram illustrating an example 2D crossbar array.

FIG. 1B is a block diagram illustrating a 3D view of an example vertical crossbar array.

FIG. 1C is a block diagram illustrating a 3D vertical RRAM crossbar array circuit in accordance with some implementations of the present disclosure.

FIGS. 2A-2F are block diagrams illustrating cross-section views of a vertical crossbar array at different stages of a first example manufacturing process in accordance with some implementations of the present disclosure.

FIG. 3 is a flowchart illustrating example steps of the manufacturing process demonstrated in FIGS. 2A-2F in accordance with some implementations of the present disclosure.

FIGS. 4A-4F are block diagrams illustrating various perspective views of the example vertical crossbar array during the manufacturing process as shown in FIGS. 2A-2F in accordance with some implementations of the present disclosure.

FIGS. 5A-5F are block diagrams illustrating various cross-section views of a vertical crossbar array at different stages of a second example manufacturing process in accordance with some implementations of the present disclosure.

FIG. 6 is a flowchart illustrating example steps of the second manufacturing process demonstrated in FIGS. 5A-5F in accordance with some implementations of the present disclosure.

FIGS. 7A-7F are block diagrams illustrating various perspective views of the second manufacturing process demonstrated in FIGS. 5A-5F.

FIG. 8 is a block diagram illustrating a top view of an example 1S1R RRAM stack in accordance with some implementations of the present disclosure.

FIG. 9 is a block diagram illustrating a top perspective view of a second example 1S1R RRAM stack in accordance with some implementations of the present disclosure.

FIG. 10 is a block diagram illustrating an example 3D One-Transistor-N-RRAM (1TNR) structure in accordance with some implementations of the present disclosure.

The implementations disclosed herein are illustrated by way of example, and not by way of limitation, in the figures of the accompanying drawings. Like reference numerals refer to corresponding parts throughout the drawings.

### DETAILED DESCRIPTION

Technologies relating to providing crossbar array circuits with one or more 3D vertical RRAMs having different architectures, as well as methods for manufacturing the same are disclosed. The technologies described in the present disclosure may provide the following technical advantages.

First, limitation on the size of a cell makes it difficult for conventional 2D RRAM crossbar array to scale. Once the size of a RRAM and the size of filaments within the RRAM are fixed to produce certain switching characteristics, it may be difficult to reduce the size of the RRAM.

Implementing a 3D vertical RRAM architecture, in contrast, allows a RRAM to be built on the vertical direction. Building an RRAM on an additional dimension enhances scalability, which is particularly beneficial when implementing RRAMs in large scale applications, for example machine learning applications.

Second, in addition to providing increased scalability, the present disclosure provides various different architectures of a 1S1R stack or 1TNR structure for optimizing the performance of a 3D vertical RRAM crossbar array circuit. The disclosed architectures may provide more effective leakage current control in a 3D vertical RRAM crossbar array circuit by allowing current to pass through only the selected RRAM cell and blocking leakage current through half-selected RRAM cells and unselected RRAM cells, which reduces the sneak path current.

Third, the disclosed processes for manufacturing a 3D vertical RRAM crossbar array circuit can achieve more cost-effectiveness and high density, and yet can be implemented using industrial standard equipment.

For instance, the present disclosure provides various methods for oxidizing the sidewall of a RRAM metal, making it less technically onerous to form an RRAM oxide without requiring the deposition of an additional RRAM oxide layer. For instance, the present disclosure describes various methods for forming an interlayer between a selector and a RRAM oxide or between an electrode and a RRAM oxide, which provide better layer-to-layer adhesion and ohmic contact and reduce serial resistance of an interface.

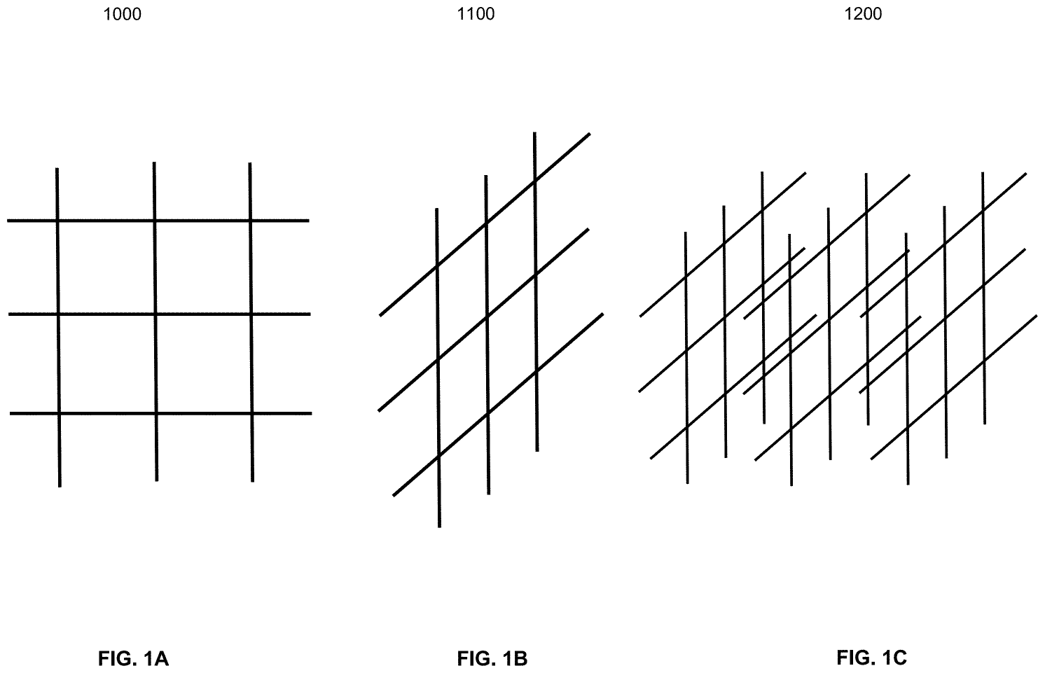

FIG. 1A is a block diagram illustrating an example 2D crossbar array 1000. In applications such as machine learning, the 2D crossbar array 1000 may perform one Vector-Matrix Multiplication (VMM) using a stored RRAM conductance as weight from each RRAM cell of the array for in-memory-computing applications.

FIG. 1B is a block diagram illustrating a 3D view of an example vertical crossbar array 1100. A horizontal 2D crossbar array becomes a 3D crossbar array in a vertical plane.

FIG. 1C is a block diagram illustrating a 3D vertical RRAM crossbar array circuit 1200 in accordance with some implementations of the present disclosure. As shown in FIG. 1C, the 3D vertical RRAM crossbar array circuit 1200 includes three RRAM crossbar array circuits positioned at three different vertical locations. Each vertical crossbar array included in the 3D vertical RRAM crossbar array circuit 1200 may perform vector matrix multiplications (VMM) on its own.

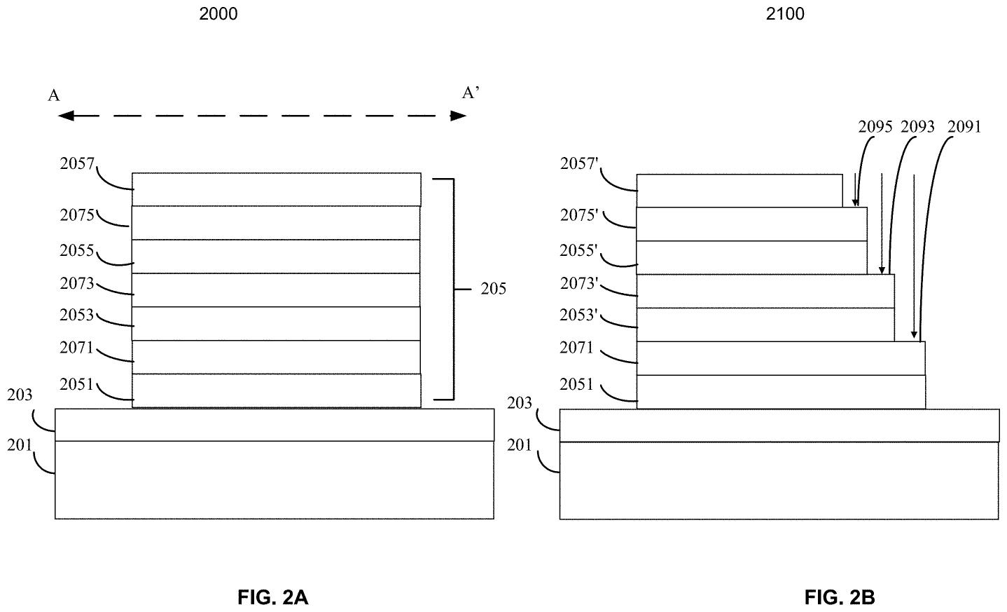

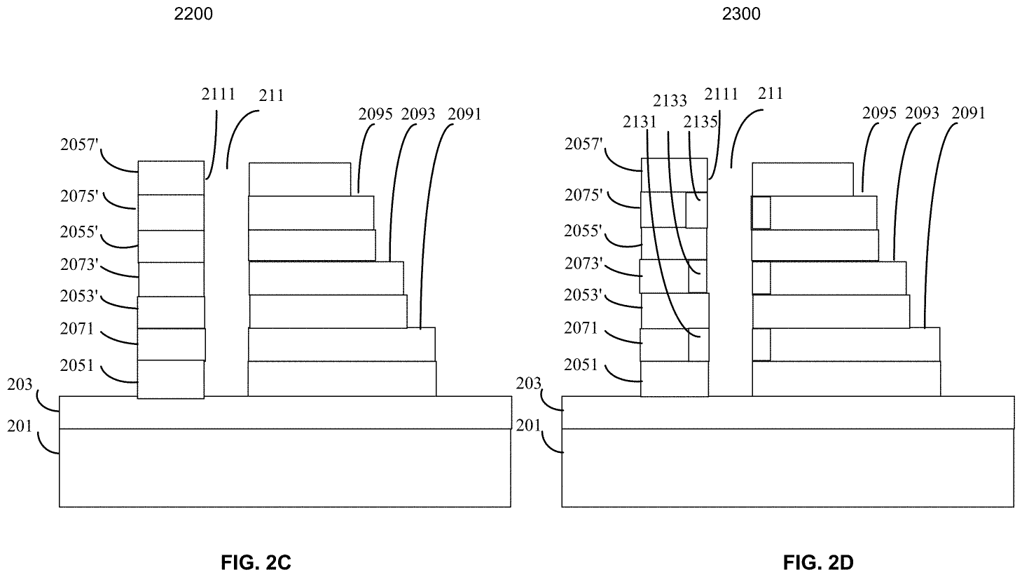

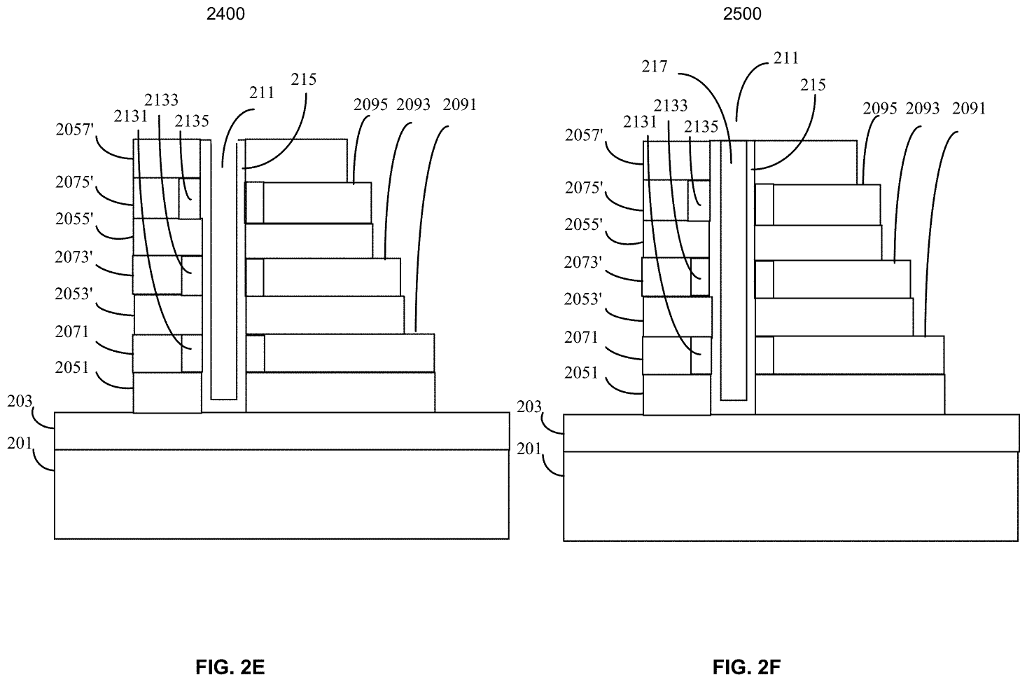

FIGS. 2A-2F are block diagrams 2000-2500 illustrating cross-section views of a vertical crossbar array at different stages of a first example manufacturing process in accordance with some implementations of the present disclosure.

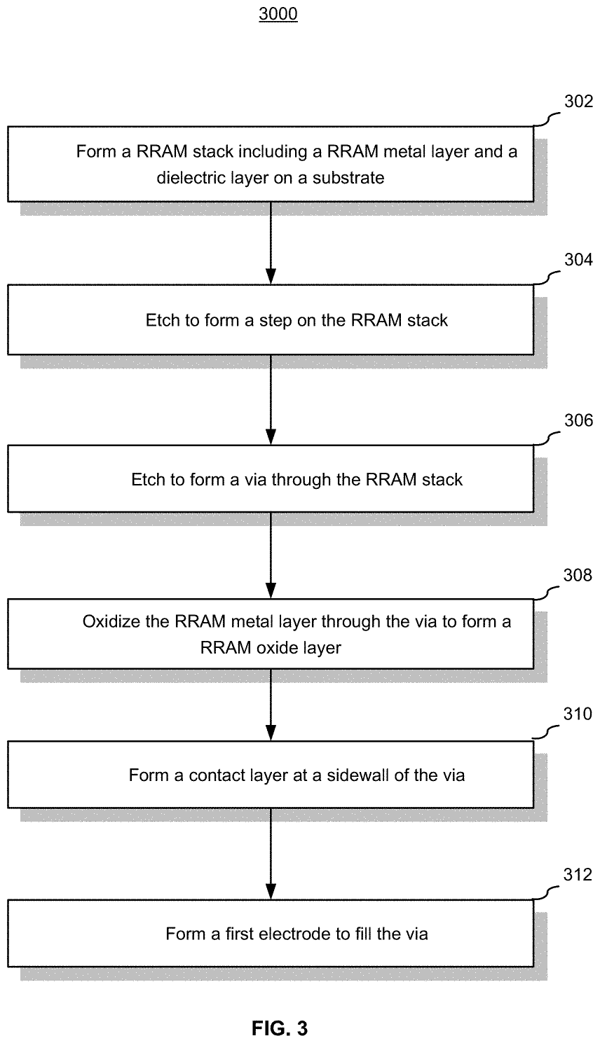

FIG. 3 is a flowchart illustrating example steps of the manufacturing process demonstrated 3000 in FIGS. 2A-2F in accordance with some implementations of the present disclosure.

In some implementations, the process 3000 beings with providing a substrate 201. The substrate 201 may include transistor arrays, integrated circuits, and interconnects. Next, an InterLayer Dielectric (ILD) 203 is formed on the substrate 201, as shown in FIG. 2A. In some implementations, after forming the ILD 203, a planarization process may be performed using a chemical or mechanical polishing equipment to smoothing the surface of the ILD 203.

The substrate 201 may be made of Si, SiO2, SiN, Al2O3, AlN, gallium arsenide, or glass. In some implementations, the substrate 201 may include one or more doped regions, for example, one or more p-doped regions and n-doped regions. In some implementations, the substrate 201 is a workpiece that supports various layers formed in and over and attached to the substrate 201. In some implementations, the ILD 203 may be made of SiO2, or SiN deposited using a Chemical Vapor Deposition (CVD) process.

Next, the process includes alternatingly depositing a plurality of dielectric layers and one or more RRAM metal layers on the ILD 203, forming a RRAM stack 205 on the ILD 203 (step 302).

The plurality of dielectric layers include, for example, a first dielectric layer 2051, a second dielectric layer 2053, a third dielectric layer 2055, and a fourth dielectric layer 2057. In some implementations, a dielectric layers (e.g., the layers 2071-2075) is made of SiO₂, SiN, or a combination thereof.

The one or more RRAM metal layers include, for example, a first RRAM metal layer 2071, a second RRAM metal layer 2073, and a third RRAM metal layer 2075. Each metal layer is patterned to form metal lines or stripes for a crossbar array. The RRAM stack 205 may include additional or fewer dielectric layers or RRAM metal layers. In some implementations, a RRAM metal layer (e.g., the layers 2071-2075) is made of Ta, Hf, Ti, Zr, or a combination thereof.

In some implementations, as shown in FIG. 2B, the process 3000 includes etching edges of the RRAM stack 205 one or more times using one or more wet etching or dry etching processes. After these etching steps, one or more upper surfaces of the RRAM metal layers (e.g., a first upper surface 2091, a second upper surface 2093, and a third upper surface 2095) are exposed. These upper surfaces may be used to connect to electrodes (e.g., Word Lines or WLs, for short).

Etching edges of the RRAM stack 205, in some implementations, includes using reactive ion etching with a predefined and exposed photoresist to form the upper surfaces (2091, 2093, and 2095). The remaining dielectric layers and RRAM metal layers are formed to have a step shape (step 304). For instance, in some implementations, a fourth dielectric layer 2057′ is etched to expose the third upper surface 2095; a third dielectric layer 2055′ and a third RRAM metal layer 2075′ are etched to expose the second upper surface 2093; and a second dielectric layer 2053′ and a second RRAM metal layer 2073′ are etched to expose the first upper surface 2091 as shown in FIG. 2B.

In some implementations, as shown in FIG. 2C, the process 3000 further includes etching a via hole (or a via for short) 211 through the RRAM stack 205, exposing the ILD 203, or a contact pad from substrate. As a result of the via etching, a sidewall 2111 of the via 211 is formed (step 306). The via etching may be a wet etching process or a dry etching process.

After the sidewall 2111 is exposed, as shown in FIG. 2D, an oxidation process may be applied to oxidize the RRAM metal layers (e.g., the first RRAM metal layer 2071, the second RRAM metal layer 2073′, and the third RRAM metal layer 2075′) through the via 211 to form RRAM oxide layers (e.g., a first RRAM oxide layer 2131, a second RRAM oxide layer 2133, and a third RRAM oxide layer 2135) (step 308). The oxidation process makes it easier to form an RRAM oxide layer. The RRAM oxide layers 2131-2135 may be made of TaOx, HfOx, TiOx, ZrOx or other metal oxide materials.

Next, as shown in FIG. 2E, the process 3000 may additional include continuously depositing a contact layer 215 along the sidewall 2111 through the via 211. The contact layer 215 is formed on an exposed surface of ILD 203 (step 310). In some implementations, the contact layer 215 is formed by using Atomic Layer Deposition (ALD) technique to form a nanoscale thin film. In some implementations, a material of the contact layer 215 is made of Pt, Pd, Ir, Ti, a combination thereof, or an alloy with any other conductive materials.

In some implementations, the contact layer 215 is formed as an adhesion layer or an ohmic contact layer between a later filled electrode layer and the sidewall by applying ALD technique to produce a thin and conformal film. In some implementations, the contact layer 215 is formed as a passivation layer to prevent the reaction or diffusion between the later filled electrode layer and the RRAM oxide layer under high temperature while RRAIVI is operating.

After forming the contact layer 215, the process 3000 may include filling and forming a first electrode layer 217 through the via 211 (step 312). The first electrode layer 217 may be made of Pt, Pd, Ir, Ru, Ti, TiN, W, Ta, Hf, Nb, V, TaN, NbN, a combination thereof or an alloy with any other conductive materials.

In some implementations, the first electrode 217 is a Bit Line (BL) or a vertical line. The combination of using the upper surfaces as word lines or horizontal lines and the first electrode 217 as a bit line or a vertical line produces a 3D vertical RRAM crossbar array circuit in accordance with some implementations of the present disclosure.

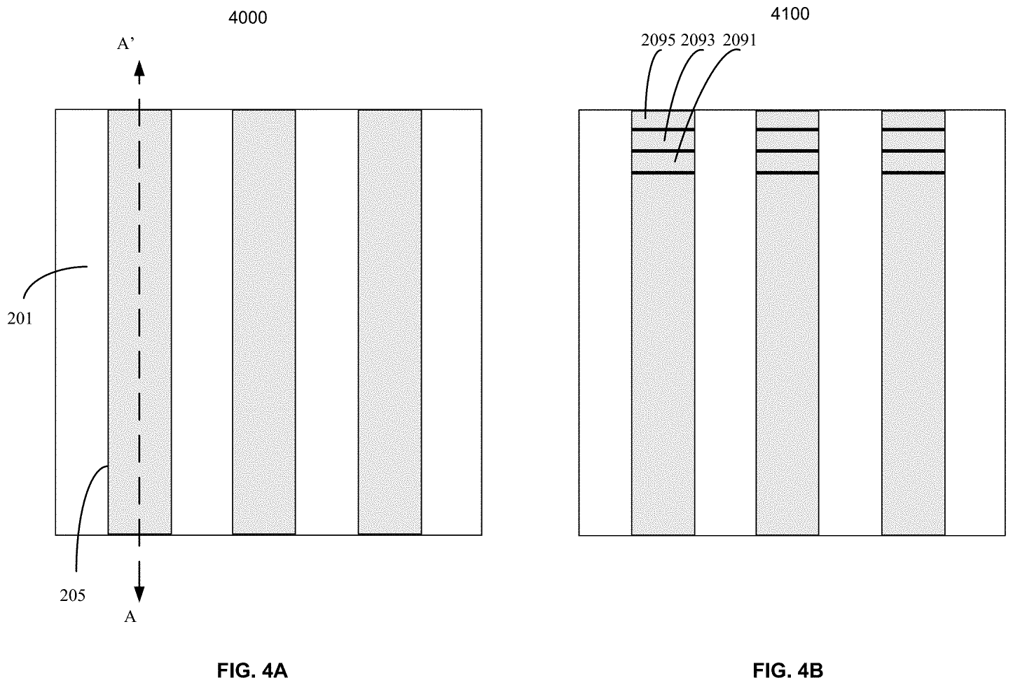

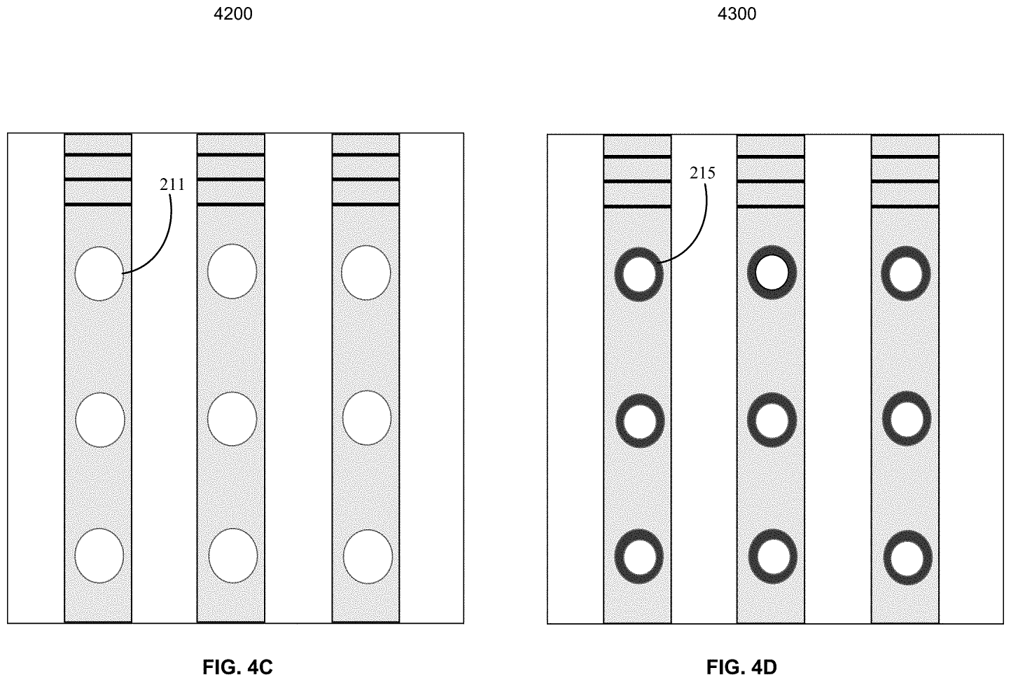

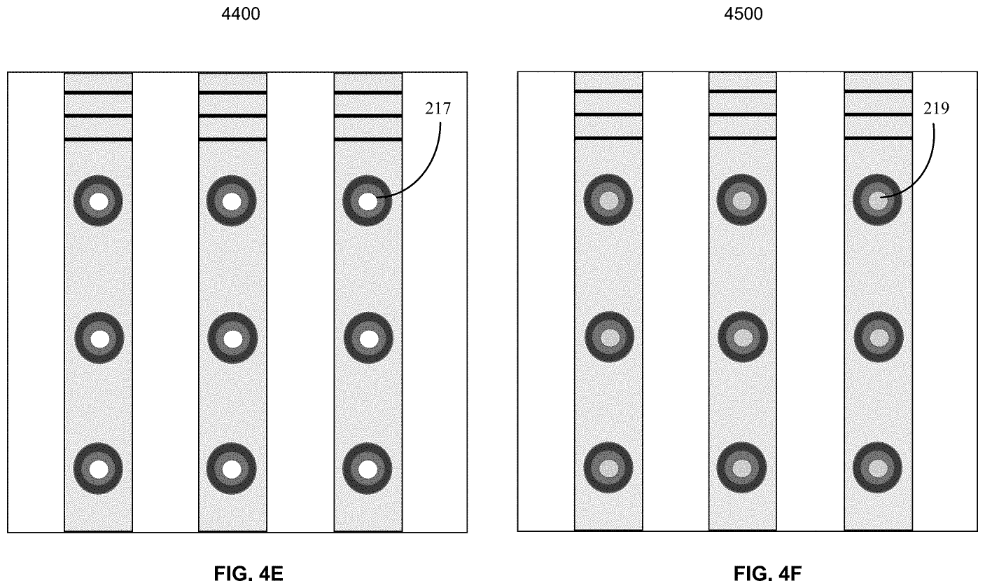

FIGS. 4A-4F are block diagrams illustrating various perspective views 4000-4500 of the example vertical crossbar array during the manufacturing process as shown in FIGS. 2A-2F in accordance with some implementations of the present disclosure. The broken line A-A′ shown in FIG. 4A represent a cut line that produces the cross-sectional view shown in FIG. 2A.

The substrate 201 is shown in FIG. 4A. The RRAM stack 205 is formed on the substrate 201 and ILD 203 in a strip shape. In some implementations, the RRAIVI stack 205 is first formed on the substrate 201 and a patterning process is then used to produce the strip shape.

As shown in FIG. 4B, edges of the RRAM stack 205 may be etched multiple times with either a wet etching process or a dry etching process, exposing one or more upper surfaces of the RRAM metal layers. These upper surfaces may be used to connect to electrodes (e.g., word lines).

Next, as shown in FIG. 4C, the via 211 is formed. As shown in FIG. 4D, an oxidation process may be applied through the via 211 to form the RRAM oxide layers 215. Then, as shown in FIG. 4E, the contact layer 217 is formed on the sidewall or the sidewalls of the RRAM oxide layers 215. Further, as shown in FIG. 4F, the first electrode 219 is filled and formed in the via 211.

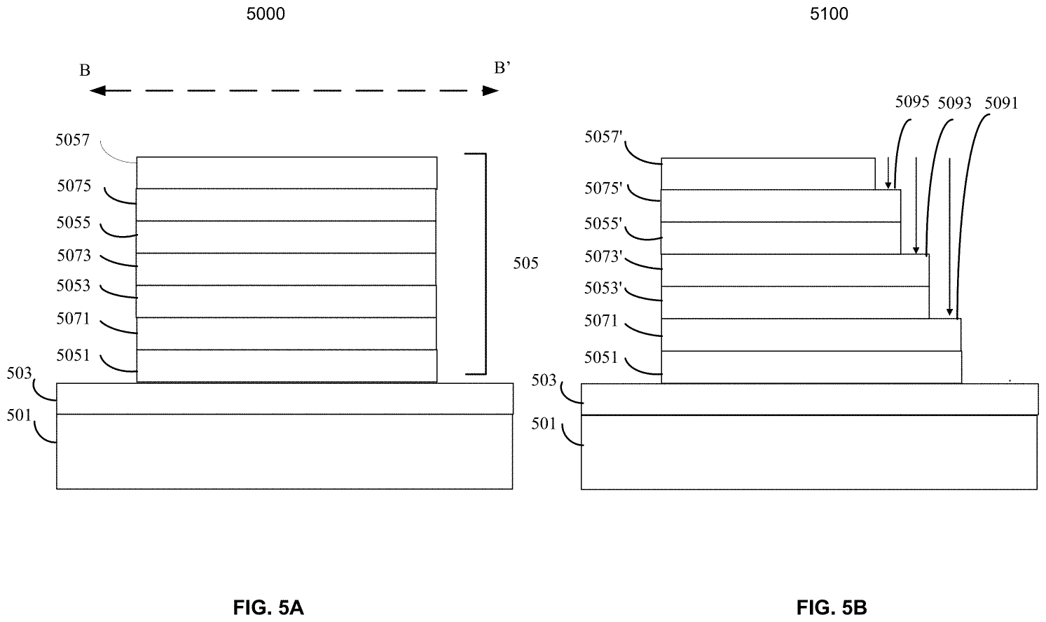

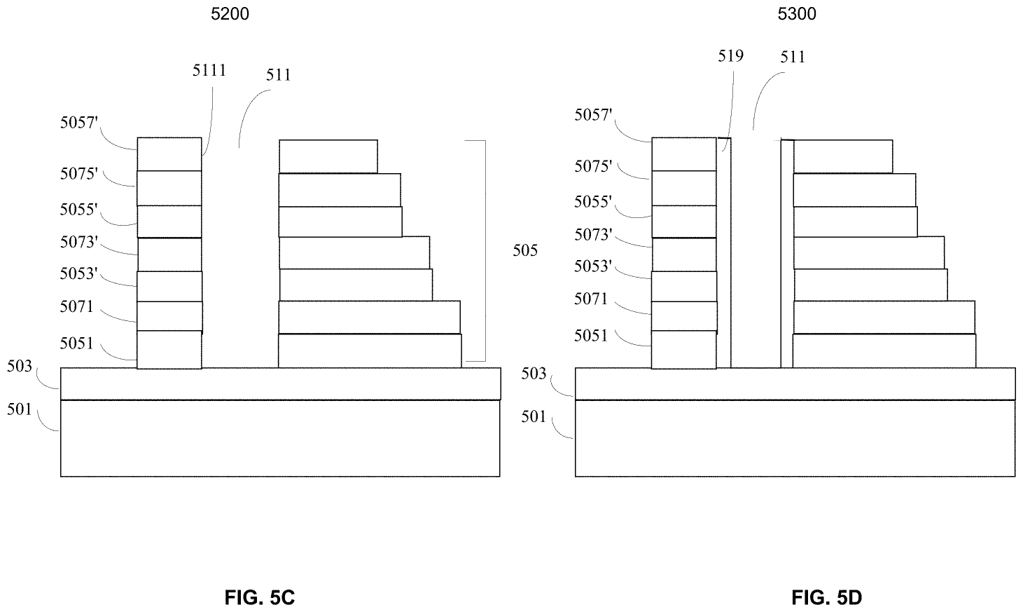

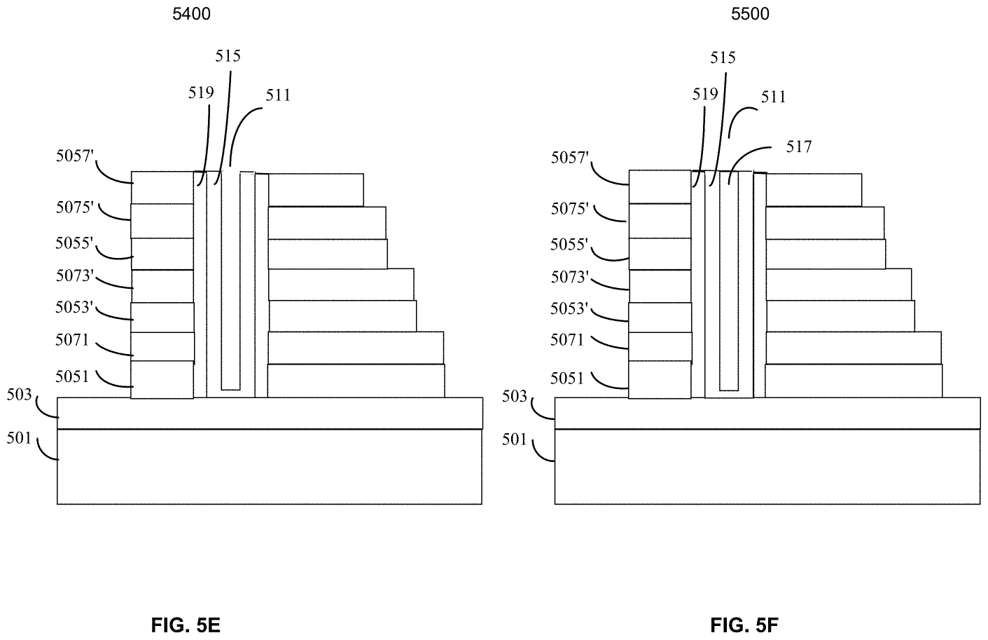

FIGS. 5A-5F are block diagrams illustrating various cross-section views 5000-5500 of a vertical crossbar array at different stages of a second example manufacturing process in accordance with some implementations of the present disclosure.

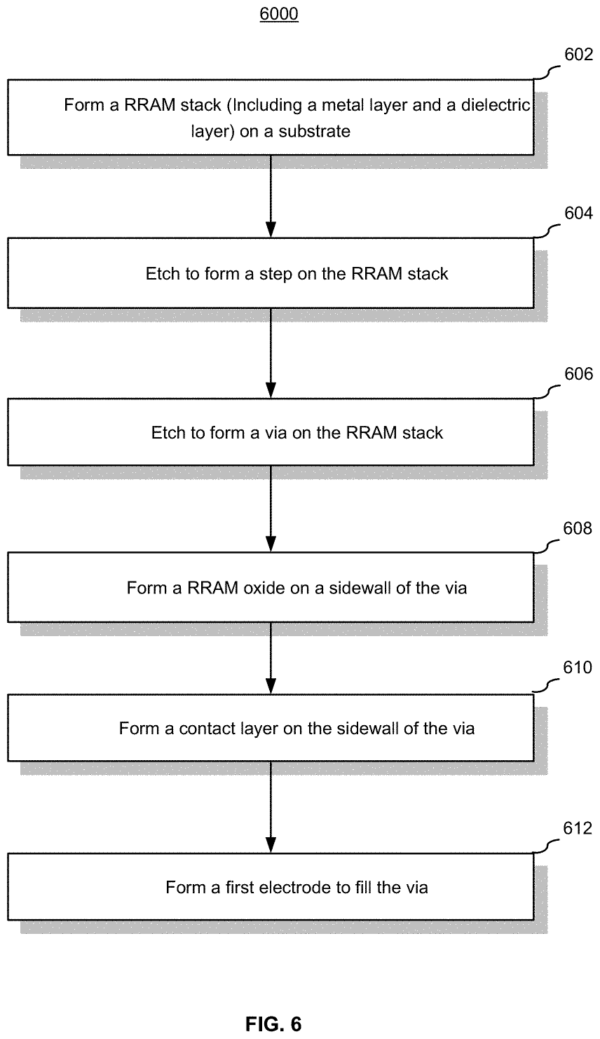

FIG. 6 is a flowchart illustrating example steps of the second manufacturing process 6000 demonstrated in FIGS. 5A-5F in accordance with some implementations of the present disclosure.

In some implementations, the process 6000 beings with providing a substrate 501. The substrate 501 may contain transistor arrays, integrated circuits and interconnects. Next, an ILD 503 is formed on the substrate 501, as shown in FIG. 5A. In some implementations, after forming the ILD 503, a planarization process may be performed using a chemical or mechanical polishing equipment to smoothing the surface of the ILD 503.

The substrate 501 may be made of Si, SiO2, SiN, Al2O3, AlN, gallium arsenide, or glass. In some implementations, the substrate 501 may include one or more doped regions, for example, one or more p-doped regions and n-doped regions. In some implementations, the substrate 501 is a workpiece that supports various layers formed in and over and attached to the substrate 501. In some implementations, the ILD 503 may be made of SiO2, or SiN deposited using a Chemical Vapor Deposition (CVD) process.

Next, the process 6000 may include alternatingly depositing a plurality of dielectric layers and one or more RRAM metal layers on the ILD 503, forming a RRAM stack 505 on the ILD 203 as shown in FIG. 5A (step 602).

The plurality of dielectric layers include, for example, a first dielectric layer 5051, a second dielectric layer 5053, a third dielectric layer 5055, and a fourth dielectric layer 5057. In some implementations, a dielectric layers (e.g., layers 5051-5057) is made of SiO₅, SiN, or a combination thereof.

The one or more RRAM metal layers include, for example, a first RRAM metal layer 5071, a second RRAM metal layer 5073, and a third RRAM metal layer 5075. The RRAM stack 505 may include additional or fewer dielectric layers or RRAM metal layers. In some implementations, a RRAM metal layer (e.g., layers 5071-5075) is made of Pt, Ti, TiN, Pd, Ir, W, Ta, Hf, Zr, Nb, V, TaN, NbN, a combination, or an alloy with any other conductive materials.

In some implementations, the process 6000 (as explained below with reference to FIGS. 5D-5E) does not include an oxidation process; as a result, a metal layer (e.g., layers 5071-5075) is not required to include Ta, Hf, Ti, Zr, a combination, or an alloy with any other conductive materials.

In some implementations, as shown in FIG. 5B, the process 6000 includes etching edges of the RRAM stack 505 one or more times using one or more wet etching or dry etching processes. After these etching steps, one or more upper surfaces of the RRAM metal layers (e.g., a first upper surface 5091, a second upper surface 5093, and a third upper surface 5095) are exposed. These upper surfaces may be used to connect to electrodes (e.g., Word Lines or WLs, for short).

Etching edges of the RRAM stack 505, in some implementations, includes using reactive ion etching with a predefined and exposed photoresist to form the upper surfaces (5091, 5093, and 5095). The remaining dielectric layers and RRAM metal layers are formed to have a step shape (step 604). For instance, in some implementations, a fourth dielectric layer 5057′ is etched to expose the third upper surface 5095; a third dielectric layer 5055′ and a third RRAM metal layer 5075′ are etched to expose the second upper surface 5093; a second dielectric layer 5053′ and a second RRAM metal layer 5073′ are etched to expose the first upper surface 5091 as shown in FIG. 5B.

In some implementations, as shown in FIG. 5C, the process 6000 further includes etching a via hole (or a via for short) 511 through the RRAM stack 505, exposing the ILD 503, or a contact feature on substrate. As a result of the via etching, a sidewall 5111 of the via 511 is formed (step 606). The via etching may be a wet etching process or a dry etching process.

After the sidewall 5111 is exposed, as shown in FIG. 5D, an RRAM oxide layer 519 may be formed continuously along the sidewall 5111 of the via 511 (step 608). The RRAM oxide layer 519 is, in some implementations, made of TaOx, HfOx, TiOx, ZrOx, or a combination thereof.

Next, as shown in FIG. 5E, the process 3000 may additionally include depositing a contact layer 515 on an exposed surface of the ILD 503 and the RRAM oxide layer 519, through the via 511 (step 610). In some implementations, the contact layer 515 is formed by using Atomic Layer Deposition (ALD) technique to form a nanoscale thin film. In some implementations, a material of the contact layer 515 is made of Pt, Pd, Ir, Ti, TiN, TaN, a combination thereof, or an alloy with any other conductive materials.

In some implementations, the contact layer 515 is formed as an adhesion layer or an ohmic contact layer between a later filled electrode layer and the sidewall by applying ALD technique to produce a thin and conformal film. In some implementations, the contact layer 515 is formed as a passivation layer to prevent the reaction or diffusion between later filled electrode layer and the RRAM oxide layer under high temperature while RRAM is operating.

After forming the contact layer 515, the process 6000 may include filling and forming a first electrode layer 517 through the via 511 (step 612). In some implementations, a material of the first electrode 517 includes Pt, Ti, TiN, Pd, Ir, W, Ta, Hf, Nb, V, TaN, NbN, or the combination or of alloy other conductive materials thereof.

In some implementations, the first electrode 517 is a Bit Line (BL) or a vertical line. The combination of using the upper surfaces as word lines or horizontal line and the first electrode 517 as a bit line or a vertical line produces a 3D vertical RRAM crossbar array circuit in accordance with some implementations of the present disclosure.

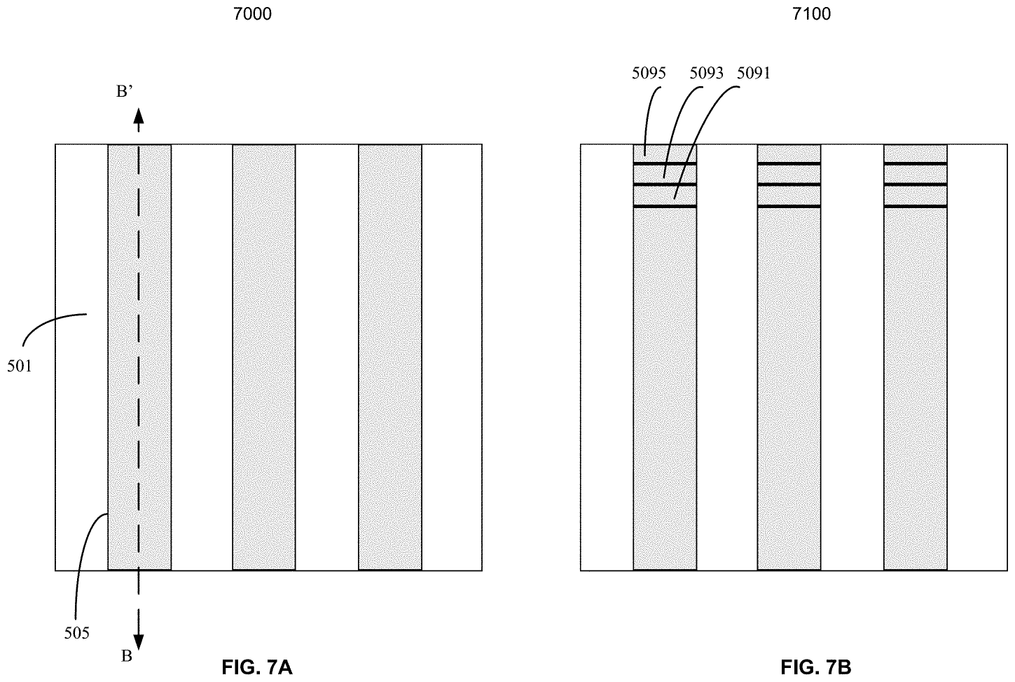

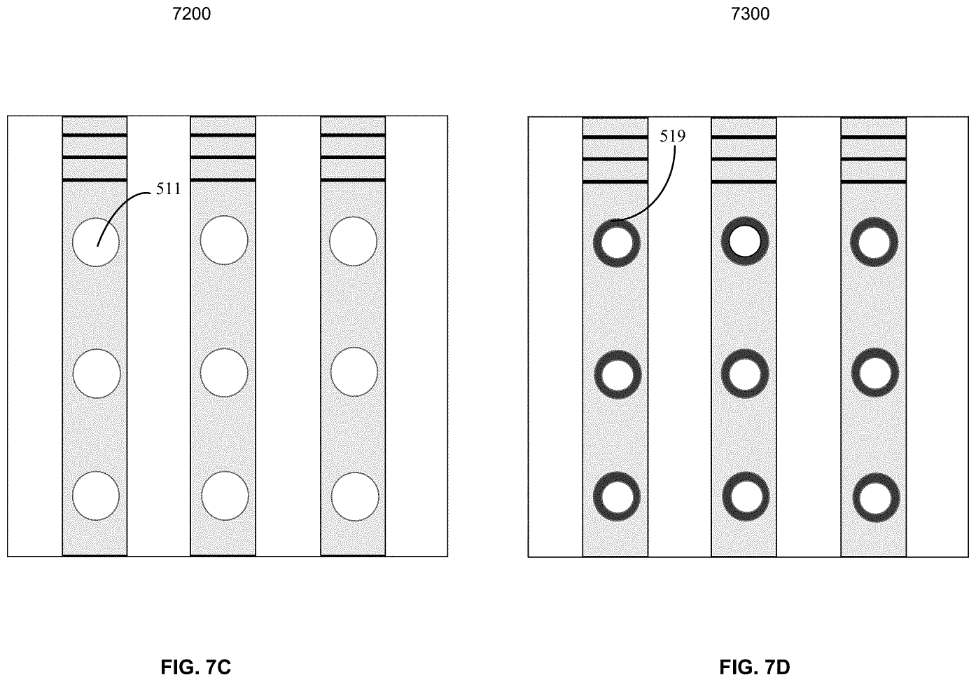

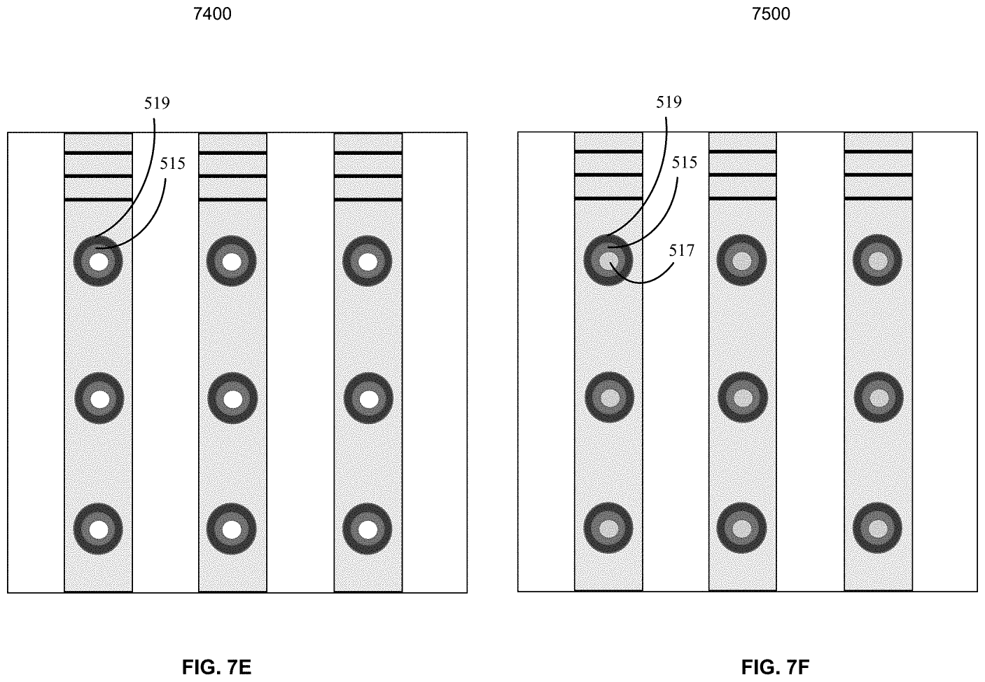

FIGS. 7A-7F are block diagrams illustrating various perspective views 7000-7500 of the example vertical crossbar array during the second manufacturing process as shown in FIGS. 5A-5F in accordance with some implementations of the present disclosure. The broken line B-B′ shown in FIG. 7A represent a cut line that produces the cross-sectional view shown in FIG. 5A.

The substrate 501 is shown in FIG. 7A. The RRAM stack 505 is formed on the substrate 501 and ILD 503 in a strip shape. In some implementations, the RRAM stack 505 is first formed on the substrate 501 and a patterning process is then used to produce the strip shape.

As shown in FIG. 7B, edges of the RRAM stack 505 may be etched multiple times with either a wet etching process or a dry etching process, exposing one or more upper surfaces of the RRAM metal layers. These upper surfaces may be used to connect to electrodes (e.g., word lines).

Next, as shown in FIG. 7C, the via 511 is formed using an etching process. The RRAM oxide layer 519 may then be formed, as shown in FIG. 7D, on the sidewall of the via 511. Then, as shown in FIG. 7E, the contact layer 515 is formed on the sidewall of the RRAM oxide layer 519. Further, as shown in FIG. 7F, the first electrode 517 is filled and formed the via 511.

FIGS. 2A-2F, 3, 4A-4F, 5A-5F, 6, and 7A-7F illustrates various example processes for manufacturing vertical 3D RRAM crossbar arrays. Example 3D vertical cross bar arrays including one or more 1S1R or 1TNR structures are explained below.

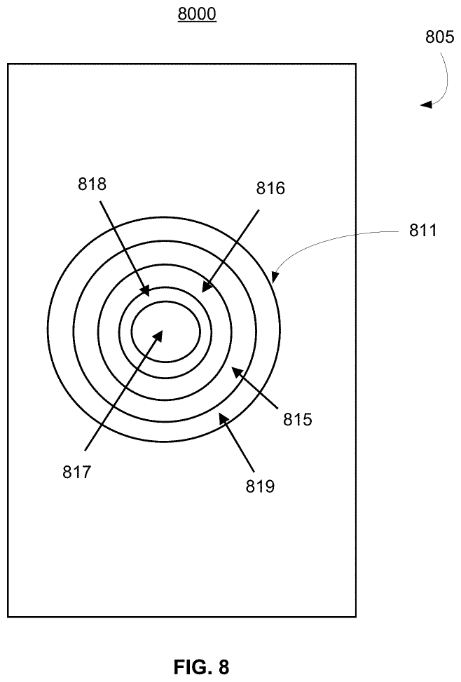

FIG. 8 is a block diagram illustrating a top view 8000 of an example 1S1R RRAM stack 805 in accordance with some implementations of the present disclosure.

As shown in FIG. 8, the 1S1R RRAM stack 805 includes dielectric layers and metal layers alternatingly deposited on an ILD layer and a substrate, as explained with reference to at least FIGS. 5A-5F, 6, and 7A-7F, and a via filled with the alternatingly deposited layers. The process for forming the via 811 may be the same as or similarly to those explained with reference to FIGS. 5A-5F, 6, and 7A-7F.

After the via 811 is formed, the 1S1R RRAM stack 805 further includes an RRAM oxide layer 819 formed in the via 811. The RRAM oxide layer 819 is located at periphery of the via 811. In some implementations, the RRAM oxide layer 819 is made of TaOₓ, HfOₓ, TiOₓ, ZrOx, or a combination thereof.

Next, a first contact layer 815 may be formed inside the RRAM oxide layer 819; a selector layer 816 may be formed inside the contact layer 815; a second contact layer 818 may be formed inside the selector layer 816; and a first electrode 817 may be formed inside the second contact layer 818. The first electrode 817 may fill the via 811. The selector layer 816 may be formed between the first contact layer 815 and the first electrode 817, and the second contact layer 818 may be formed between the selector layer 816 and the first electrode 817.

The first contact layer 815 is, in some implementations, made of Pt, Pd, Ir, Ti, a combination thereof, or an alloy with any other conductive materials.

The selector layer 816 includes, in some implementations, an Insulator-Metal Transition (IMT), a Mott transition, or a Negative-Differential-Resistance (NDR). The IMT may be of an N-shape and controlled by voltage or of an S-shape and controlled by current. The selector layer 816 is, in some implementations, made of NbOx; the second contact layer 818 is, in some implementations, made of Nb; the first electrode layer 817 includes, in some implementations, Pt, Ti, TiN, Pd, Ir, W, Ta, Hf, Nb, V, TaN, NbN, a combination thereof, or an alloy with any other conductive materials.

As shown in FIG. 8, the 1S1R RRAM stack 805 includes a WL (e.g., the second electrode 5071 as shown in FIG. 5F) connected to the 1R (e.g., the RRAM oxide layer 819), which is connected to Pt (e.g., the first contact layer 815), which is further connected to the 1S (e.g., the selector layer 816), which is connected to Nb (e.g., a second contact layer 818), which is connected to a BL (e.g., the first electrode layer 817).

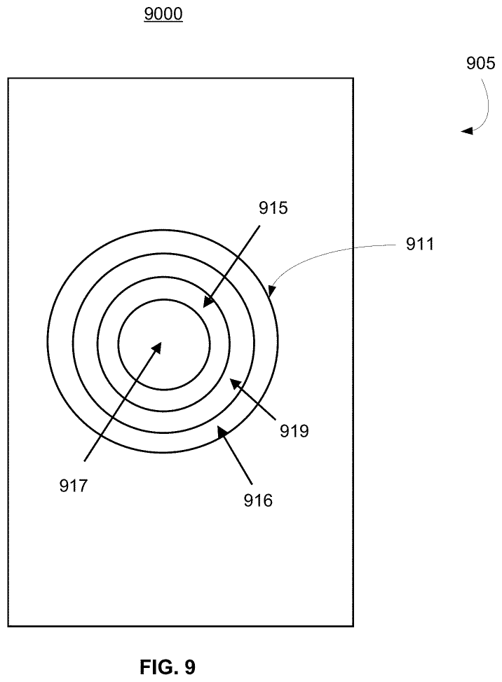

FIG. 9 is a block diagram 9000 illustrating a top view of a second example 1S1R RRAM stack 905 in accordance with some implementations of the present disclosure.

As shown in FIG. 9, the 1S1R RRAM stack 905 includes dielectric layers and metal layers alternatingly deposited on an ILD layer and a substrate, as explained with reference to at least FIGS. 5A-5F, 6, and 7A-7F, and a via filled with the alternatingly deposited layers. The process for forming the via 911 may be the same as or similarly to those explained with reference to FIGS. 5A-5F, 6, and 7A-7F.

The 1S1R RRAM stack 905 may further include a selector layer 916 formed inside the via 911. The selector layer 916 is located at periphery of the via 911.

The selector layer 916 includes, in some implementations, an Insulator-Metal Transition (IMT), a Mott transition, or a Negative-Differential-Resistance (NDR). The IMT may be of an N-shape and controlled by voltage or of an S-shape and controlled by current. The selector layer 916 is, in some implementations, made of NbOx.

Next, an RRAM oxide layer 919 is formed within a circle of the selector layer 916; a first contact layer 915 is formed within a circle of the RRAM oxide layer 919, and; a first electrode 917 is formed within a circle of the first contact layer 915 and filled the via 911. In some other implementations, a contact layer may be formed between selector layer 916 and RRAM oxide layer 919.

In some implementations, the RRAM oxide layer 919 is made of: TaOx, HfOx, TiOx, ZrOx, or a combination thereof. In some implementations, the first contact layer 915 is made of: Pt, Pd, Ir, Ti, a combination thereof, or an alloy thereof with one or more other conductive materials.

In some implementations, the first electrode layer 917 is made of Pt, Ti, TiN, Pd, Ir, W, Ta, Hf, Nb, V, TaN, NbN, a combination thereof, or an alloy thereof with one or more other conductive materials.

As shown in FIG. 9, the 1S1R RRAM stack 905 includes a WL (e.g., the second electrode 5071 as shown in FIG. 5F) connected to the 1S (e.g., the selector layer 916), which is connected to a 1R (e.g., the RRAM oxide layer 919), which is connected to Pt (e.g., the first contact layer 915), which is further connected to a BL (e.g., the first electrode layer 917).

As explained above, the selector may reduce sneak path current (e.g., unintended electrical path current). For instance, the selector may use an IMT, which, when selected, makes the selector become conductive (e.g., metallic) (ON under full voltage V), and, when half-selected or unselected, makes the selector become insulated (OFF under +/−half voltage V/2 or no voltage 0V). These techniques minimize the sneak path current, when an RRAM is not selected. Also, using a suitable selector instead of a transistor (which may be a 1T1R structure) saves chip space. Further, a selector being a two-terminal device makes circuit design simpler and power consumption lower, compared to using a 1T1R structure.

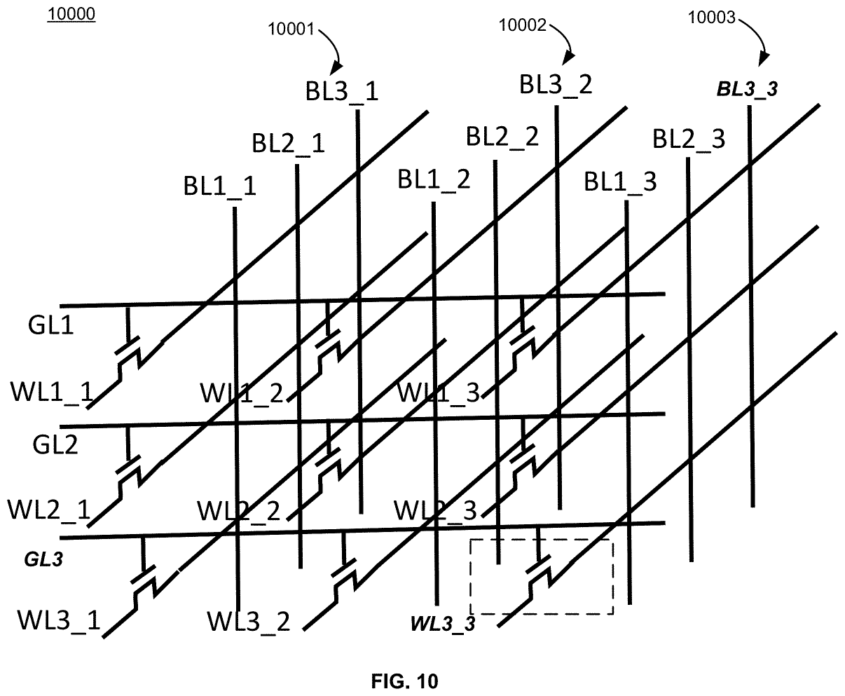

FIG. 10 is a block diagram illustrating an example 3D One-Transistor-N-RRAM (1TNR) structure 10000 in accordance with some implementations of the present disclosure.

As a three-terminal device, a transistor may require more chip space and a larger number of interconnects than an RRAM cell does. For 3D RRAM cross bar arrays, 1T1R array circuits may become too expensive to build, because transistors cannot be stacked up in 3D and the area occupied by transistors may become too large.

In contrast, the 1TNR crossbar array circuits described in the present disclosure may reduce the total number of transistors required, increase the chip density, reduce circuit interconnects, and reduce the cost. One of the many key technical advantages provided by a 1TNR is that transistor is a mature technology, while selector technology is less mature.

As shown in FIG. 10, three crossbar arrays (10001, 10002, and 10003) may be positioned on parallel vertical planes and connected with each other to form a 3D 1TNR structure. Each crossbar array may perform vector matrix multiplications on it own. Because crossbar arrays can be positioned vertically, these implementations are technically advantageous because they provide greater scalability by taking advantage of the vertical space, even when the surface area is limited.

As also shown in FIG. 10, due to the additional space availability in the vertical direction, the 3D 1TNR structure 10000's scalability is less constrained by the size of a cell. Also, because the spacing between arrays 10001, 10002, and 10003 are adjustable, great density may be achieved.

As shown in FIG. 10, BLs represent bit lines, which are vertical lines connected to a first electrode (e.g., the first electrode 517 or 517) through a via. WLs represent word lines, which are horizontal lines connected to an array of second electrodes. GLs represent gate lines, which are horizontal lines connected to transistors located on a layer within a 3D RRAM stack. The source of the transistors is connected to a WL. If one WL is connected to N RRAM, the one transistor is implemented to select one of the N RRAM on this WL in 1TNR drive scheme.

Example steps for selecting a device located at the cross point of WL3_3 and BL3_3 may include:

applying V_{G} on GL3 and maintaining V_{G}=0 on other GLs, causing the transistor channels on GL3 to open;

applying VD on the transistor Drain connected to WL3_3 and maintaining VD=0 on other transistors located on the same horizontal layer, causing current to be able to pass through only WL3_3; and

applying V_{ground} to BL3_3 and maintaining Vs (which equals to V_{D}-V_{DS}) on other BLs intersecting with WL3_3,

where V_{S} represents the voltage at a transistor's source; and V_{DS} represents a voltage drop across the transistor's drain and its source.

As seen, only one device on a WL is programmed by the voltage difference between V_{S} and V_{ground}. Other devices on the same WL are not programmed, due to the lack of voltage difference on those devices. A 1TNR drive scheme may therefore be implemented by using a 3D vertical RRAM crossbar array circuit in accordance with some implementations of the present disclosure.

Plural instances may be provided for components, operations or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first column could be termed a second column, and, similarly, a second column could be termed the first column, without changing the meaning of the description, so long as all occurrences of the “first column” are renamed consistently and all occurrences of the “second column” are renamed consistently. The first column and the second are columns both column s, but they are not the same column.

The terminology used herein is for the purpose of describing particular implementations only and is not intended to be limiting of the claims. As used in the description of the implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined (that a stated condition precedent is true)” or “if (a stated condition precedent is true)” or “when (a stated condition precedent is true)” may be construed to mean “upon determining” or “in response to determining” or “in accordance with a determination” or “upon detecting” or “in response to detecting” that the stated condition precedent is true, depending on the context.

The foregoing description included example systems, methods, techniques, instruction sequences, and computing machine program products that embody illustrative implementations. For purposes of explanation, numerous specific details were set forth in order to provide an understanding of various implementations of the inventive subject matter. It will be evident, however, to those skilled in the art that implementations of the inventive subject matter may be practiced without these specific details. In general, well-known instruction instances, protocols, structures, and techniques have not been shown in detail.

The foregoing description, for purpose of explanation, has been described with reference to specific implementations. However, the illustrative discussions above are not intended to be exhaustive or to limit the implementations to the precise forms disclosed. Many modifications and variations are possible in view of the above teachings. The implementations were chosen and described in order to best explain the principles and their practical applications, to thereby enable others skilled in the art to best utilize the implementations and various implementations with various modifications as are suited to the particular use contemplated.

What is claimed is:

1. A 3D One-Transistor-N-RRAM (1TNR) structure comprising:
a plurality of gate lines; and
a plurality of crossbar arrays, including a first crossbar array and a second crossbar array, wherein
the first crossbar array is positioned on a first vertical plane;
the second crossbar array is positioned on a second vertical plane different from the first vertical plane;
each crossbar array in the plurality of crossbar arrays includes a first plurality of bit lines and a second plurality of word lines;
each word line in the second plurality of word lines is connected to a source and a destination of a second transistor;
each gate line in the plurality of gate lines is connected to a gate of a first transistor located in the first crossbar array and a gate of a second transistor located in the second crossbar array.

2. The 3D One-Transistor-N-RRAM (1TNR) structure of claim 1, wherein the plurality of crossbar arrays includes a third crossbar array positioned on a third vertical plane different from both the first crossbar array and the second crossbar array.

3. The 3D One-Transistor-N-RRAM (1TNR) structure of claim 2, wherein the third crossbar array includes a plurality of word lines and a plurality of bit lines, wherein each word line in the plurality of word lines is connected to a source and a destination of a third transistor.

4. The 3D One-Transistor-N-RRAM (1TNR) structure of claim 3, wherein a gate of a third transistor in the third crossbar array is connected to a gate line in the plurality of gate lines.

5. A method of manufacturing a crossbar array circuit comprising:
providing a substrate;
alternatingly depositing, on the substrate, one or more RRAM metal layers and one or more dielectric layers to form an RRAM stack on the substrate;
etching the RRAM stack to form a via;
oxidizing the one or more RRAM metal layers through the via to form one or more RRAM oxide layers;
forming a contact layer on a sidewall of the via; and
forming a first electrode to fill the via.

6. The method as claimed in claim 1, further comprises:
forming one or more transistor arrays, integrated circuits, and interconnects on the substrate before forming the RRAM stack.

7. The method as claimed in claim 1, further comprises:
etching the RRAM stack to expose one or more upper surfaces of the one or more RRAM metal layers.

8. An apparatus comprises:
a substrate;
an ILD formed on the substrate;
an RRAM stack formed on the ILD, wherein the RRAM stack comprises one or more metal layers and one or more dielectric layers alternatingly deposited on the ILD;
a via formed within the RRAM stack, wherein the via comprises a sidewall;
an RRAM oxide layer formed on the sidewall of the via;
a first contact layer formed on the RRAM oxide layer through the via; and
a first electrode formed on the first contact layer and filled the via.

9. The apparatus as claimed in claim 4, wherein substrate comprises one of: Si, SiO2, SiN, Al2O3, AlN, gallium arsenide, or glass.

10. The apparatus as claimed in claim 5, wherein the RRAM oxide layer is made of TaOₓ, HfOₓ, TiOₓ, ZrOₓ, or a combination thereof.

11. The apparatus as claimed in claim 5, wherein the first contact layer comprises: Pt, Pd, Ir, Ti, a combination thereof, or an alloy of a conductive material and one or more of: Pt, Pd, Ir, and Ti.

12. The apparatus as claimed in claim 5, wherein the first electrode comprises: Pt, Ti, TiN, Pd, Ir, W, Ta, Hf, Nb, V, TaN, NbN, a combination thereof, or an alloy of a conductive material and one or more of: Pt, Ti, TiN, Pd, Ir, W, Ta, Hf, Nb, V, TaN, NbN.

13. The apparatus as claimed in claim 5, further comprises:
a selector layer formed between the first contact layer and the first electrode; and
a second contact layer formed between the selector layer and the first electrode;

14. The apparatus as claimed in claim 13, wherein the selector layer comprises: an insulator-metal transition (IMT), a Mott transition, or a negative-differential-resistance (NDR).

15. An apparatus comprises:
a substrate;
an ILD formed on the substrate;
an RRAM stack formed on the ILD, wherein the RRAM stack comprises one or more metal layers and one or more dielectric layers alternatingly deposited on the ILD;
a via formed within the RRAM stack, wherein the via comprises a sidewall;
a selector layer formed on the sidewall through the via;
an RRAM oxide layer formed on the selector layer through the via;
a first contact layer formed on the RRAM oxide layer; and
a first electrode formed on the first contact layer and filled the via.

16. The apparatus as claimed in claim 13, wherein the RRAM oxide layer comprises TaOₓ, HfOₓ, TiOₓ, ZrOₓ, or a combination thereof.

17. The apparatus as claimed in claim 13, wherein the selector layer comprises: an Insulator-Metal Transition (IMT), a Mott transition, or a Negative-Differential-Resistance (NDR).
